(19) United States
(12) Patent Application Publication
(10) Pub. No.: US 2008/0206957 A1
(43) Pub. Date: Aug. 28, 2008

(54) Method of Forming Isolation Layer of Semiconductor Memory Device

(75) Inventors: Kwang Hyun Yun, Icheon-si (KR); Min Sik Jang, Icheon-si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-si (KR)

(21) Appl. No.: 11/951,308

(22) Filed: Dec. 5, 2007

(30) Foreign Application Priority Data
Feb. 26, 2007 (KR) 2007-18981

(51) Int. Cl. H01L 21/62

(52) U.S. Cl. 438/430; 257/E21.52

(57) ABSTRACT

The present invention relates to a method of forming an isolation layer of a semiconductor memory device. After a trench is formed by etching a semiconductor substrate, a liner insulating film is formed from a DCS-HTO material having a similar wet etch rate to that of a PSZ film that gap fills an isolation layer, and the trench is gap filled with the PSZ film. Accordingly, in a subsequent etch process for EFH control of the isolation layer, residues do not remain on sidewalls of a conductive film for a floating gate, thereby improving electrical properties of devices.

### CROSS-REFERENCES TO RELATED APPLICATIONS

This patent claims priority to Korean patent application number 10-2007-18981

filed on Feb. 26, 2007, the disclosure of which is incorporated by reference in its entirety.

### TECHNICAL FIELD

This patent relates to a method of forming an isolation layer of a semiconductor memory device and, more particularly, to a method of forming an isolation layer of a semiconductor memory device, where the isolation layer is formed from a polysilazene (PSZ) film.

### BACKGROUND OF THE INVENTION

In a semiconductor circuit, unit elements formed on a semiconductor substrate, such as a transistor, a diode and/or a resistor are electrically isolated in an isolation process. The isolation process is an initial step in an overall semiconductor manufacturing process, resulting the size of an active region and process margin of a subsequent step.

A LOCal Oxidation of Silicon (LOCOS) method is employed as the isolation process. In the LOCOS isolation method, as oxygen is infiltrated from the bottom of a nitride film, the nitride film is used as a mask selectively oxidization of a semiconductor substrate to the side of a pad oxide film, thereby generating a bird's beak at the end of a field oxide film. The bird's beak causes the field oxide film to extend into the active region, so that the channel length is shortened and the threshold voltage is increased. Consequently, there arises a problem in which, for example, an electrical characteristic of aggravating the transistor occurs.

Another isolation method, for example, a Shallow Trench Isolation (STI) process has emerged to solve problems, such as unstable factors, including degradation of the field oxide film depending on a reduction in the design rule of semiconductor devices, and a reduction in the active region according to the bird's beak.

FIG. 1 is a sectional view of a device illustrating a conventional method of forming an isolation layer of a semiconductor memory device.

In the conventional method of forming a STI type isolation layer, a tunnel insulating film 11 and a conductive film 12 for a floating gate are formed over a semiconductor substrate 10. The conductive film 12 for the floating gate, the tunnel insulating film 11, and the semiconductor substrate 10 are selectively etched to form a trench 10a. A liner insulating film 13 is then formed over the entire surface. An isolation layer is formed using a PSZ film 14 having a good gap-fill characteristic. Thereafter, in order to control the Effective Field Height (EFH) of the isolation layer, top surfaces of the isolation layer comprised of the PSZ film 14 and the liner insulating film 13 are etched using an etching process.

Since the PSZ film 14 and the liner insulating film 13 have different etch rates, the liner insulating film 13 may remain on the sidewalls of the conductive film 12 for the floating gate during the etching process. This degrades an interface characteristic of the conductive film 12 and an oxide-nitride-oxide (ONO) dielectric layer in a subsequent deposition process of the ONO dielectric layer, which leads to degraded electrical properties of the device.

### BRIEF SUMMARY OF THE INVENTION

This patent is directed to a method of forming an isolation layer of a semiconductor memory device, wherein it can improve electrical properties of devices by preventing residues from remaining on sidewalls of a conductive film for a floating gate in a subsequent etching process for EFH control of an isolation layer. A trench is formed by etching an isolation region of a semiconductor substrate. A liner insulating film is formed over an overall surface including the trench. The liner insulating film may be a Dichlorosilane-High Temperature Oxide (DCS-HTO) material having a similar wet etch rate to a PSZ film that gap fills the isolation layer. The PSZ film is formed over the entire surface including the liner insulating film so that the trench is gap filled with the PSZ film.

In an embodiment of the invention, a method of forming an isolation layer of a semiconductor memory device includes forming a tunnel insulating film, a conductive film for a floating gate, and a hard mask film over a semiconductor substrate. The hard mask film may be a pad nitride film. The hard mask film, the conductive film, the tunnel insulating film, and the semiconductor substrate are etched, for example, using an etching process, thus forming a trench. A liner insulating film is formed over an overall surface including the trench. An insulating film is deposited over an overall surface including the liner insulating film. A polishing process is performed to expose a top surface of the hard mask film. The hard mask film is later removed and the top surfaces of the liner insulating film and the insulating film are etched, for example, using the etching process in order to control an Effective Field Height (EFH) of an isolation layer. The liner insulating film may be formed from a DCS-HTO material.

In an embodiment of the invention, the liner insulating film may be formed, for example, using N₂O: DCS gases in a ratio of approximately 20:1 to 3000:1 at a temperature ranging from 700 to 850 degrees Celsius and a pressure ranging from 50 to 500 Torr.

In an embodiment of the invention, the insulating film may be formed from, for example, a polysilazene (PSZ) film to a thickness of approximately 4000 to 6000 angstrom, for example, using a spin coating method.

After the formation of the insulating film, the method further includes performing a curing process employing O₂ and H₂ at a temperature ranging from 300 to 600 degrees Celsius and a pressure ranging from 200 to 500 Torr in order to remove impurities within the insulating film, before the polishing process.

1 In an embodiment of the invention, the process of removing the hard mask may be performed, for example, using phosphoric acid for approximately 10 to 30 minutes. The control of the EFH of the isolation layer may be performed, for example, using H₂O and O₂ having a ratio of approximately 100:1 for approximately 5 to 10 minutes.

### BRIEF DESCRIPTION OF THE DRAWINGS

FIG. 1 is a sectional view of a device for illustrating a conventional method of forming an isolation layer of a semiconductor memory device; and

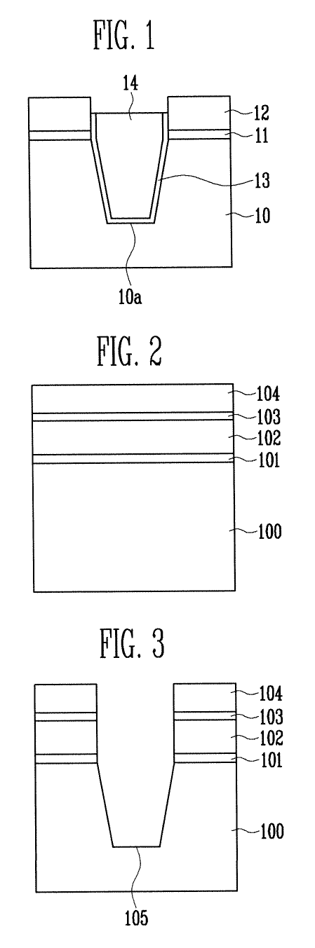

FIGS. 2 to 6 are sectional views of a device for illustrating a method of forming an isolation layer of a semiconductor memory device according to an embodiment of the present invention.

### DESCRIPTION OF SPECIFIC EMBODIMENTS

Hereinafter, a method of forming an isolation layer of a semiconductor memory device in accordance with a preferred embodiment of the invention will be described in detail with reference to the accompanying drawings.

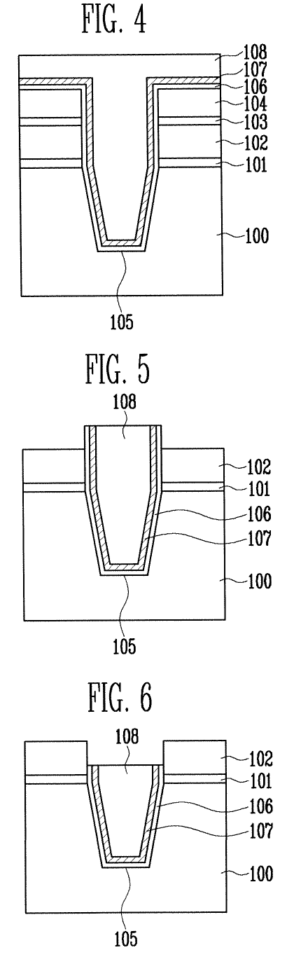

Referring to FIG. 2, a tunnel insulating film 101, a conductive film 102 for a floating gate, a buffer oxide film 103, and a pad nitride film 104 are formed over a semiconductor substrate 100. The tunnel insulating film 101 may be formed, for example, from an oxide film. The tunnel insulating film 101 may be formed by depositing the film to a thickness of approximately 70 to 80 angstrom using a wet oxidization process. A Nitrous Oxide (N₂O) annealing process is performed using nitrogen to reduce the trap charge density and improve reliability. The conductive film 102 may be formed from a dual film, for example, an amorphous polysilicon film not containing impurities and a polysilicon film containing impurities. The conductive film 102 may be formed, for example, using Silane (SiH₄) gas and Phosphine (PH₃) gas as source gases at a temperature ranging from 500 to 550 degrees Celsius. The conductive film 102 may be formed to a thickness of approximately 300 to 1500 angstrom. The buffer oxide film 103 may be formed to a thickness of approximately 30 to 100 angstrom for the purpose of stress mitigation with the conductive film 102 for the floating gate and the pad nitride film 104. The buffer oxide film 103 may be formed, for example, using a Low-Pressure Chemical Vapor Deposition (LPCVD) method. The pad nitride film 104 may be formed to a thickness of approximately 300 to 1000 angstrom, for example, using a LPCVD method.

To form a trench 105 (as depicted in FIG. 3), the pad nitride film 104, the buffer oxide film 103, the conductive film 102 for the floating gate, the tunnel insulating film 101, and the semiconductor substrate 100 may be etched using an etching process.

Referring to FIG. 4, an oxidization process is performed, for example, using a wall oxide film 106 over the entire surface including the trench 105. The wall oxide film 106 functions to mitigate etch damage occurs during the trench etching process and further reduces a Critical Dimension (CD) of an active region. A liner insulating film 107 is formed over the entire surface including the trench 105, for example, using the oxidization process. The liner insulating film 107 may be formed, for example, from DCS-HTO. The liner insulating film 107 may be formed, for example, using N₂O:DCS gases in a ratio of 20:1 to 3000:1. The liner insulating film 107 may be formed at a temperature ranging from 700 to 850 degrees Celsius and a pressure ranging from 50 to 500 Torr. DCS-HTO has reflectance of approximately 1.4 to 1.45 and has a similar physical property to an oxide film having reflectance of 1.46 formed, for example, using a thermal oxidization process. Further, oxygen and silicon have a composition ratio of approximately 1.9:1 to 2.1:1 and has a similar physical property to the thermal oxidization film. DCS-HTO has a density of 2.0 g/cm³, which is lower than the thermal oxidization film having a density of 2.3 g/cm³. Thus, the liner insulating film 107 has a similar etch rate to an insulating film 108 formed from a PSZ material having a high wet etch rate. This is due to the fact that the bonds of oxygen and silicon are weaker than the thermal oxidization film and has a relatively low coupling energy.

The PSZ film 108 is formed over the entire surface including the liner insulating film 107, thereby gap filling the trench 105. The PSZ film 108 may be formed to a thickness of approximately 4000 to 6000 angstrom, for example, using a spin coating method. In order to remove impurities within the PSZ film 108, a curing process employing O₂ and H₂ having a ratio of 2:1 may be preferably carried out at a temperature ranging from 300 to 600 degrees Celsius and a pressure ranging from 200 to 500 Torr.

Referring to FIG. 5, a polishing process, for example, is performed to expose a top surface of the pad nitride film 104 (As shown in FIG. 4). The pad nitride film 104 is then removed, for example, using an etching process. The etching process may be performed, for example, using phosphoric acid (H₃PO₄) for approximately 10 to 30 minutes. Thereafter, the buffer oxide film 103 is removed, for example, using a cleaning process.

Referring to FIG. 6, top surfaces of the isolation layers 106, 107, and 108 are etched, for example, using the etching process by controlling a target so that the EFH of the isolation layers becomes a desired level. The etching process may be performed, for example, using H₂O and O₂ having a ratio of 100:1 for approximately 5 to 10 minutes. The liner insulating film 107 and the PSZ film 108 having a similar etch rate are etched without residues on the sidewalls of the conductive film 102 for the floating gate, thereby improving the electrical properties of the devices.

Although preferred embodiments of the invention have been disclosed for illustrative purposes, it is to be understood that changes and modifications of the invention may be made by the ordinary skilled in the art without departing from the spirit and scope of the invention as defined in the accompanying claims.

What is claimed is:

1. A method of forming an isolation layer of a semiconductor memory device, comprising:
forming a trench by etching an isolation region of a semiconductor substrate;
forming a liner insulating film over an overall surface including the trench;
depositing an insulating film over the overall surface including the liner insulating film until the trench is gap-filled, defining an isolation layer; and
etching a top surface of the isolation layer to control an Effective Field Height (EFH) of the isolation layer.

2. The method of claim 1, wherein the isolation region comprising:
forming a tunnel insulating film, a conductive film for a floating gate, and a hard mask film over the semiconductor substrate.

3. The method of claim 2, further comprising:
polishing the overall surface until a top surface of the hard mask film is exposed; and
removing the hard mask film before etching the top surface of the isolation layer.

4. The method of claim 1, wherein the liner insulating film is a Dichlorosilane-High Temperature Oxide (DCS-HTO) film.

5. The method of claim 1, wherein the liner insulating film is formed using N₂O:DCS gases in a ratio of 20:1 to 3000:1.

6. The method of claim 1, wherein the liner insulating film is formed at a temperature ranging from 700 to 850 degrees Celsius and a pressure ranging from 50 to 500 Torr.

7. The method of claim 1, wherein the insulating film is a polysilazene (PSZ) film.

8. The method of claim 1, wherein the insulating film is formed to a thickness of about 4000 to 6000 angstrom using a spin coating method.

9. The method of claim 2, further comprising, before polishing the overall surface, curing the insulating film in order to remove impurities within the insulating film.

10. The method of claim 3, wherein the curing process is performed by O₂ and H₂ at a temperature ranging from 300 to 600 degrees Celsius and a pressure ranging from 200 to 500 Torr.

10. The method of claim 2, wherein the process of removing the hard mask is performed using phosphoric acid for approximately 10 to 30 minutes.

11. The method of claim 1, wherein the control of the EFH of the isolation layer is performed using H₂O and O₂ having a ratio of 100:1 for approximately 5 to 10 minutes.

12. A method of forming an isolation layer of a semiconductor memory device, comprising:
forming a tunnel insulating film, a conductive film for a floating gate, a buffer oxide film, and a pad nitride film on a semiconductor substrate;
etching at least a portion of the tunnel insulating film, the conductive film for a floating gate, the buffer oxide film, the pad nitride film and a semiconductor substrate, defining a trench;
forming a DCS-HTO oxide film on an overall surface including the trench;
depositing a PSZ film on an overall surface including the DCS-HTO oxide film, thus gap filling the trench to form an isolation layer;
curing the PSZ film until an impurity within the PSZ film is removed; and
etching at least a portion of the isolation layer in order to control an EFH, thereby preventing residues from remaining on sidewalls of the conductive film for a floating gate.

13. The method of claim 12, further comprising:
polishing the overall surface until a top surface of the pad nitride film is exposed; and
removing the pad nitride film and the buffer oxide film until the conductive film is exposed.

14. The method of claim 12, wherein the curing process is performed by O₂ and H₂ at a temperature ranging from 300 to 600 degrees Celsius and a pressure ranging from 200 to 500 Torr.

15. The method of claim 13, wherein the process of removing the pad nitride film and the buffer oxide film is performed using phosphoric acid for approximately 10 to 30 minutes.

16. The method of claim 12, wherein the control of the EFH of the isolation layer is performed using H₂O and O₂ having a ratio of 100:1 for approximately 5 to 10 minutes.
